(19) United States
(12) Patent Application Publication
(10) Pub. No.: US 2025/0123598 A1
(43) Pub. Date: Apr. 17, 2025

(54) ELECTRONIC MODULE AND ELECTRONIC TIMEPIECE

(71) Applicant: CASIO COMPUTER CO., LTD., Tokyo (JP)

(72) Inventors: Yuta SAITO, Tokyo (JP); Masataka IIDA, Tokyo (JP); Naoto FUKUSHIMA, Tokyo (JP)

(21) Appl. No.: 18/915,940

(22) Filed: Oct. 15, 2024

(30) Foreign Application Priority Data
Oct. 16, 2023 (JP) 2023-178124

(51) Int. Cl. G04G 17/04; G04G 17/06; H05K 1/11

(52) U.S. Cl. CPC G04G 17/04; G04G 17/06; H05K 1/112

(57) ABSTRACT

An electronic module includes, a first circuit substrate that includes, a first connector on a first surface, and a second connector on a second surface on an opposite side of the first surface, wherein the first connector and the second connector are electrically connected; an analog block that includes a third connector, wherein the third connector is connected to the first connector; and a second circuit substrate that includes a fourth connector, wherein the fourth connector is connected to the second connector. A position of the first connector is different from a position of the second connector in planar perspective. The analog block includes a projecting portion that includes an opposing surface opposing to the first surface of the first circuit substrate and including at least a partial range of the second connector and the fourth connector, wherein the opposing surface is projected toward the first circuit substrate.

### CROSS-REFERENCE TO RELATED APPLICATIONS

This application claims the benefit of Japanese Patent Application No. 2023-178124, filed Oct. 16, 2023 which is hereby incorporated by reference herein in its entirety.

### BACKGROUND OF THE INVENTION

### Field of the Invention

The present disclosure relates to an electronic module and an electronic timepiece.

### Description of the Related Art

For example, as disclosed in JP No. 2018-9934, there is a conventional technique of connecting two circuit substrates in a timepiece. One circuit substrate is connected to a timepiece movement. The technology is disclosed in which the connection between these two circuit substrates located across the housing is stabilized by an inter-connector that is resilient and located within the housing.

### SUMMARY OF THE INVENTION

An electronic module according to the present disclosure includes: a first circuit substrate that includes, a first connector on a first surface, and a second connector on a second surface on an opposite side of the first surface, wherein the first connector and the second connector are electrically connected; an analog block that includes a third connector, wherein the third connector is connected to the first connector of the first circuit substrate; and a second circuit substrate that includes a fourth connector, wherein the fourth connector is connected to the second connector of the first circuit substrate, wherein, a position of the first connector is different from a position of the second connector in planar perspective, and the analog block includes a projecting portion that includes an opposing surface opposing to the first surface of the first circuit substrate and including at least a partial range of the second connector and the fourth connector, wherein the opposing surface is projected toward the first circuit substrate.

Further features of the present invention will become apparent from the following description of exemplary embodiments (with reference to the attached drawings).

### BRIEF DESCRIPTION OF THE DRAWINGS

FIG. 1 is a front view of an electronic timepiece according to a first embodiment.

FIG. 2 is an exploded oblique view describing a structure of an electronic module according to the first embodiment.

FIG. 3A is a plan view showing a top surface of a first circuit substrate.

FIG. 3B is a bottom view showing a bottom surface of a first circuit substrate.

FIG. 4 is a plan view showing a top surface of a second circuit substrate.

FIG. 5 shows a partial cross-sectional view of an electronic module including one projecting portion.

FIG. 6 is an oblique view showing a bottom surface side of a second circuit substrate.

FIG. 7 is an exploded oblique view describing a structure of an electronic module according to a second embodiment.

FIG. 8 shows a partial cross-sectional view of the electronic module including one projecting portion according to the second embodiment.

FIG. 9 is a plan view showing a top surface of a first circuit substrate according to a modified example.

### DETAILED DESCRIPTION

Hereinafter, embodiments of the present disclosure are described with reference to the drawings.

### First Embodiment

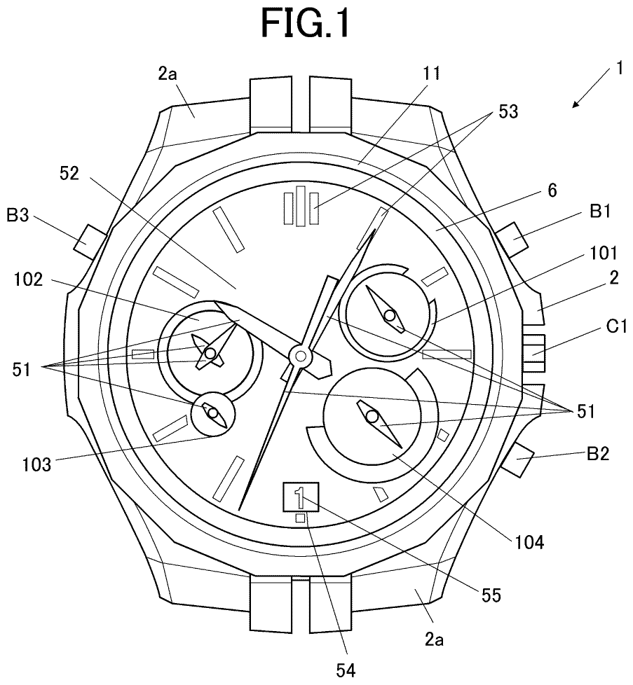

FIG. 1 is a front view of an electronic timepiece 1 according to a first embodiment.

The electronic timepiece 1 includes a housing 2, a dial 52, a hand 51, a bezel 11, and a handling acceptor that accepts handling from outside such as push button switches B1 to B3 or a crown C1. The hand 51 is rotatably positioned on the dial 52, and contents according to a direction pointed by the hand 51 are displayed on the dial 52. The contents displayed by the hand 51 include displaying the time (may be the date and time including the date and the day of the week). On the dial 52, an index (hour marker 53) is positioned to indicate displayed time.

Small windows 101 to 104 (dials) that occupy part of the dial 52 are positioned on the dial 52. Some of the hands 51 can rotate and operate inside each of these small windows 101 to 104 to display the day of the week, alarm setting time, time in other cities of the world (including UTC), and 24-hour time.

The dial 52 also includes an opening 54 at a 6 o'clock direction. Below (on a back surface side) the dial 52 is located a day wheel 55, and rotation of the day wheel 55 selectively displays an index in the shape of a numeral corresponding to the date (date index) through the opening 54. The day wheel 55 is located between two concentric circles with different radiuses, and a numerical shape member is supported by a support arm extending from the two concentric circles. Therefore, light is transmitted in areas other than the numerical shape member.

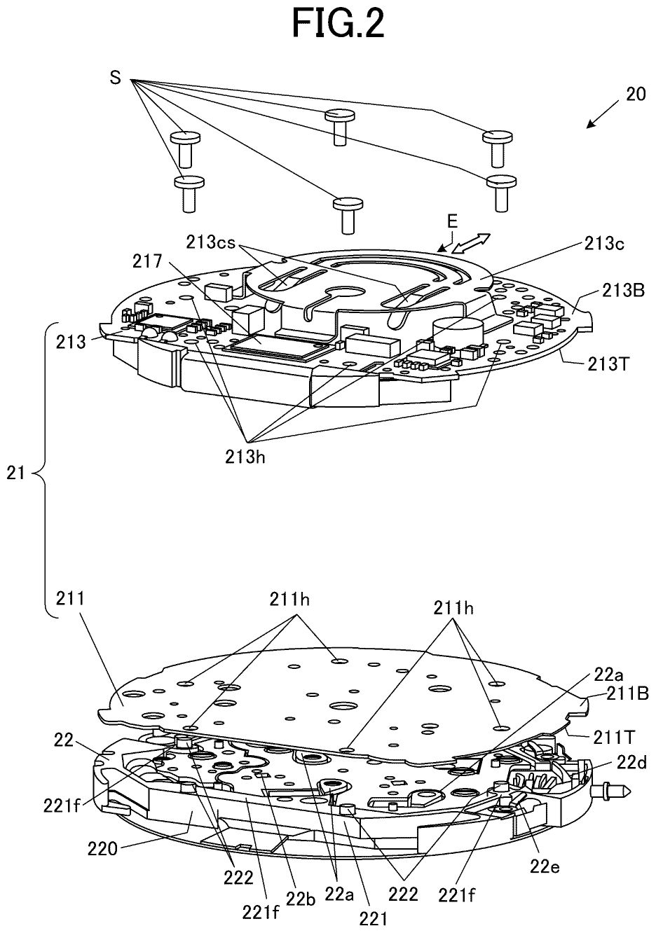

The housing 2 including a cylindrical shape with open top and bottom surfaces, and inside are the above-mentioned hands 51, day wheel 55, dial 52, and hour markers 53. In addition to the above, the housing 2 also houses an electronic module 20 (see FIG. 2), which includes a circuit 21 (see FIG. 2) and an analog block 22 (see FIG. 2). The circuit 21 includes a microcomputer 217 (computer; see FIG. 2) that controls a timekeeping operation and display operation by the hand 51. The analog block 22 includes a stepping motor that rotates the hands 51 and the day wheel 55. The push button switches B1 to B3 and the crown C1 protrude outward from lateral sides of the housing 2. Electrical signals for such handling are transmitted through the housing 2 to the circuit substrate inside. In a 12 o'clock direction and the 6 o'clock direction of the housing 2, a belt attachment portion 2a extends outward from the housing 2 in a plan view viewed from above a display surface by the hands 51. The housing 2 may be an insulating material such as resin or ceramic, or a metallic material such as titanium. A lower end (rear side) of the housing 2 is sealed by the back cover, which is not shown.

Above the dial 52 and the hands 51 (the upper end of the housing 2, surface side) is covered by a transparent wind shield material, which seals the housing 2. The periphery of the dial 52 is enclosed by a panel cover 6. Some or all of the hour markers 53, etc., may be fixed to the panel cover 6. Below the dial 52 and the day wheel 55, a solar panel is located in an annular pattern along an inner circumference of the panel cover 6. Partially located on the light-receiving surface of the solar panel are components with low or no light transmittance, such as the outer frames of the small windows 101 to 104, the hour marker 53, and the date index on the day wheel 55.

The bezel 11 is located at the periphery of the electronic timepiece 1. Such bezel 11 may include indexes pointed by the hand 51. The bezel 11 can also be used for decorative purposes. Furthermore, the electronic clock 1 may function as an antenna element when the electronic clock 1 is receiving radio waves or communicating.

FIG. 2 is an exploded oblique view describing a structure of the electronic module 20 according to the present embodiment.

The electronic module 20 includes the circuit 21 and the analog block 22. The circuit 21 receives the power supply and controls the operation of the electronic timepiece 1. The analog block 22 is a collection of configurations in which analog signals are input, output or generated in response to operations or an operation is performed in response to input signals. The analog block 22 is located on the display surface side (top side) of the electronic clock 1, and the circuit 21 is located below it (back surface side). The circuit 21 and the analog block 22 are secured to each other by screws, mainly small size screws such as screws S, in an overlapping state. The type of screw S, etc., should be determined arbitrarily according to the required intensity, space, etc.

The various components of the analog block 22 are fixed to a supporter 220. The analog block 22 may include some or all of the following types of components, for example, a stepping motor that rotates and operates the hand 51, a handling detection mechanism 22e for the push button switches B1 to B3 and a handling detection mechanism 22d for the crown C1, a lighting operation part for LED lights, a vibration motor or beep sound generator for notifying, or the like. Conventional well-known configurations that detect pressing or rotating handling may be used for the handling detection mechanisms 22d, 22e, etc.

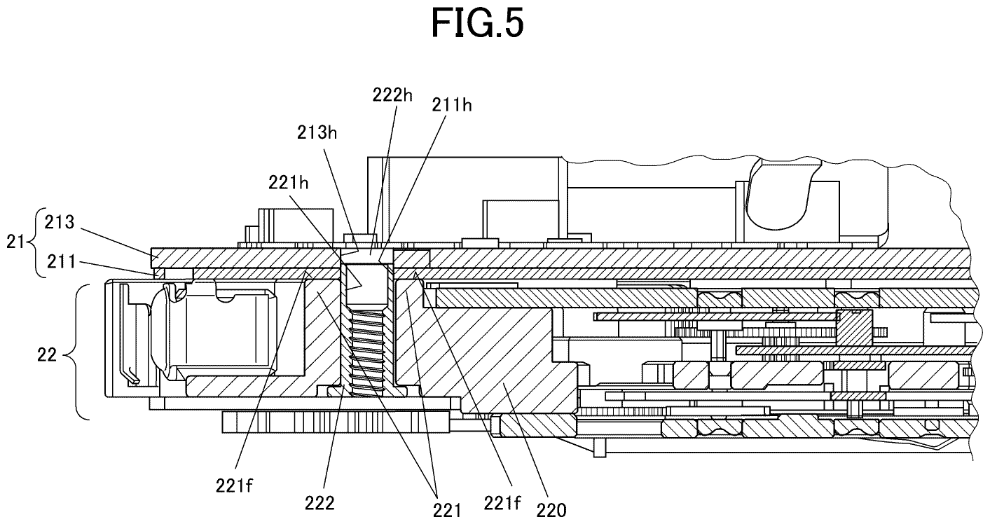

On the bottom surface side of the analog block 22, which is the side of the first circuit substrate 211 of the circuit 21, are located the connection terminal 22a of the motor, the connection terminal 22b of the detector, and the connection terminal of the solar cell, which are not shown. These connection terminals 22a, 22b, the solar cell connection terminal and the handling detection mechanisms 22d, 22e, etc. correspond to a third connector of the present embodiment. The supporter 220 of the analog block 22 includes a projecting portion 221 that projects to the side of the first circuit substrate 211. The projecting portion 221 includes an opposing surface 221f that faces a top surface 211T of the first circuit substrate 211. On the opposing surface 221f, holes 221h (see FIG. 5) are located at multiple locations, here six, as described below. A post 222 that protrudes further from the opposing surface 221f is located inside the hole 221h. The post 222 is used to fix the circuit 21 and the analog block 22 by screwing in the screw S mentioned above. The projecting portion 221 may be commonly connected to the plurality of posts 222. The four posts 222 shown in FIG. 2 are located on the opposing surface 221f of the common projecting portion 221.

The circuit 21 includes a first circuit substrate 211 and a second circuit substrate 213. The second circuit substrate 213 is a common substrate and operates as a conventional control substrate. The following electronic components are located on the bottom surface 213B side of the second circuit substrate 213, for example, the microcomputer 217 (controller) including a CPU (Central Processing Unit) and RAM (Random Access Memory), memory such as flash memory, and a module controlling wireless communication. A battery compartment 213c is located in substantially the center of the bottom surface 213B of the second circuit substrate 213, and accommodates a battery inserted from an insertion port E side. A top surface 213T of the second circuit substrate 213 opposes to a bottom surface 211B of the first circuit substrate 211.

The second circuit substrate 213 may be a laminated substrate or a double-sided substrate, depending on the patterning of the necessary wiring, etc. The first circuit substrate 211 may be a double-sided substrate that is thinner than the second circuit substrate 213. In particular, it is recommended that the first circuit substrate 211 be as thin as possible. This reduces the increase in thickness of the electronic timepiece 1 due to the added thickness of the first circuit substrate 211, as opposed to the second circuit substrate 213, which tends to be the same thickness as before. In view of the above, substrate material of the first circuit substrate 211 and the second circuit substrate 213 do not necessarily have to be the same.

The second circuit substrate 213, the first circuit substrate 211, and the analog block 22 are aligned by the post 222, a first through hole 211h, and a second through hole 213h. With the alignment in place, the screw S is screwed into the hole in the post 222 to secure the second circuit substrate 213, the first circuit substrate 211, and the analog block 22. In the fixed state, a head of the screw S is located inside the second through hole 213h and does not protrude from the bottom surface 213B (fourth surface) of the second circuit substrate 213.

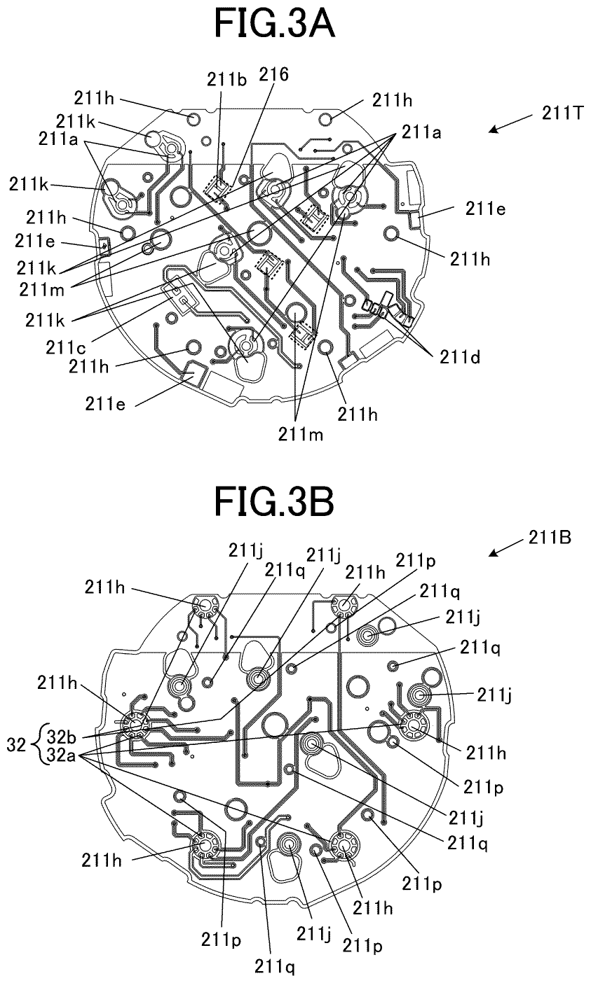

FIG. 3A is a plan view showing the top surface 211T of the first circuit substrate 211. FIG. 3B is a bottom view showing the bottom surface 211B of the first circuit substrate 211.

The top surface 211T (first surface) shown in FIG. 3A is the surface on the side facing the analog block 22. The following are positioned on the top surface 211T, for example, a connection pad 211a of the stepping motor, a phototransistor 216 used to detect the hand (light receiving element; outer frame displayed by dotted lines) and its connection pad 211b, a connection pad 211c of the solar panel, a handling detector 211d of the push button switches B1 to B3, and a handling detector 211e of the crown C1. Signal wiring extends from the above connection pads 211a, 211b, 211c and handling detectors 211d, 211e to through vias that connect the top surface side and the bottom surface side of the first circuit substrate 211, respectively.

These planar positions of the connection pads 211a and 211c and the handling detectors 211d and 211e are respectively the positions of the motor connection terminal 22a, the solar cell connection terminal, the handling detection mechanism 22d of the crown C1, and the handling detection mechanism 22e of the push button switches B1 to B3 in the analog block 22 correspondingly connected to each other. Connection here does not mean fixed joining by means of a joining member or the like. It should be at least in contact with a secure electrical connection. On the other hand, the connection between the connection terminal and the connection pad may have fitting portions according to unevenness, etc. These connection pads 211a to 211c, the handling detectors 211d and 211e, and the connection pad of the connection terminal of the solar cell correspond to a first connector of the present embodiment. The plan view position of these third and first connectors can be designed and changed for each model of the electronic timepiece.

A through hole is located in the analog block 22 at a position that overlaps with the phototransistor 216 in plan view. The through hole allows the external light from the display surface side to pass through. A gear transmitting the rotation of the above-mentioned stepping motor to the hand 51 is further located in the plan view position of the through hole. When the gear with the through hole rotates and the planar position of the through hole in the gear and the through hole in the analog block 22 overlap, external light reaches the phototransistor 216 and the detected light amount increases. This identifies the position of the hand 51 according to the angle of rotation of the gear. Furthermore, a plurality of gears that transmit rotation to a certain hand 51 may each be provided with the through hole. When all of these multiple through holes overlap in plan view with the through holes of the analog block, external light may reach the phototransistor 216.

The through hole in the analog block 22 corresponding to one of the phototransistors 216 may be located in a position that does not overlap with the gear in plan view. This phototransistor 216 detects the light amount of external light that enters from the display surface side without being shielded by the gear. This light amount or a value lower than this light amount may be set as a threshold value at which another phototransistor 216 detects external light. In other words, if another phototransistor 216 detects an external light with the light amount greater than the threshold value, the corresponding hand is identified as being in the detection position by the phototransistor 216.

The phototransistor 216, which detects external light without being shielded by gears or other devices, may further be used to detect nighttime or dark rooms. If the detected light amount of this phototransistor 216 remains lower than the reference value for a certain amount of time, it may be judged to be at night or in a drawer. In this case, the electronic timepiece 1 may automatically enter a sleep mode in which operation and power consumption are limited. In the sleep mode, for example, the operation of the second hand may be stopped or communication operations may be aborted. The automatic transition to sleep mode (auto sleep function) may be based on the detection of external light by the phototransistor 216 as well as the detection of motion by an acceleration sensor or other sensor.

The bottom surface 211B (second surface) shown in FIG. 3B is the surface of the first circuit substrate 211 on the opposite side from the above described top surface 211T and is the surface facing the second circuit substrate 213. The locations of the above through vias are the same on the top surface 211T and the bottom surface 211B. The signals that the first connector on the top surface 211T transmits and receives to and from the third connector are transmitted and received to and from the second circuit substrate 213 by the second connection pad 32 (second connector) located on the bottom surface 211B. The through hole and the second connection pad 32 are connected by signal wiring and electrically connected. The signal wiring pattern may be designed accordingly, without a specific pattern, etc.

The second connection pads 32 are divided into a plurality of groups and each group includes a plurality of second connection pads 32 aligned together. For example, in the four second connection pad groups 32a, the second connection pads 32 are arranged in an annular pattern at roughly equal angular intervals in eight directions with respect to the center position of the first through hole 211h. In the other two second connection pad groups 32b, the second connection pads 32 are arranged in a circular arc in six directions, excluding the two adjacent directions out of eight directions at roughly equal angular intervals with respect to the center position of the first through hole 211h. In other words, the position of the second connection pad 32 is different from that of the first connector in planar perspective.

The first circuit board 211 is provided with a screw hole 211j for fixing the stepping motor and a hole 211k to avoid a projecting portion of the fixed stepping motor, in this case a coil part, from contacting the first circuit substrate 211. When the stepping motor is directly mounted on the first circuit board 211, the coil portion of the stepping motor protrudes to a position where it intersects the plane containing the top surface 211T of the first circuit substrate 211. In contrast, in the first circuit substrate 211, the hole 211k is located so that the coil portion of the stepping motor includes the position intersecting with the plane including the top surface 211T of the first circuit substrate 211 when the stepping motor is directly mounted. Therefore, in the electronic module 20, the stepping motor can be directly mounted on the first circuit substrate 211 while avoiding contact of the coil portion of the stepping motor with the first circuit substrate 211. Once the stepping motor is fixed to the first circuit substrate 211, the stepping motor is inspected to see if it rotates the gears properly. In this inspection, a detection hole 211q is a hole between the first circuit substrate 211 and the supporter of the analog block 22, where the rotation of the gear is visible.

When the first circuit substrate 211 is assembled and fixed in the electronic module 20, a positioning pin is inserted into the positioning hole 211p in the first circuit substrate 211 to align it with other components. This allows for easy and accurate positioning. The through hole 211m is located where the analog block 22 could contact the first circuit substrate 211 if the analog block 22 is deflected when the hand 51 is incorporated and secured to the analog block 22. This prevents trouble such as the analog block 22 contacting and scratching the first circuit substrate 211 during assembly and manufacturing of the electronic module 20.

All of these holes, that is, the screw hole 211j, the hole 211k, the detection hole 211q, the positioning hole 211p, and the through hole 211m, are located corresponding to the configuration of the analog block 22. In other words, when the analog block 22 is changed, the formation position of these holes must also be changed to correspond to the analog block 22. With all these holes located on the first circuit board 211, for example, if the position of the stepping motor in the analog block 22 is changed, the position of the hole on the first circuit substrate 211 need only be correspondingly changed.

Conversely, if at least some of these holes are located on the second circuit substrate 213, the location of the holes on the second circuit substrate 213 will need to be changed as the analog block 22 is modified. Therefore, the second circuit substrate 213 is not a common substrate. Alternatively, if the position of the stepping motor of the analog block 22 is regulated to match the position of the hole located on the second circuit substrate 213 which is the common substrate, the design freedom of the second circuit board 211 and analog block 22 will be reduced.

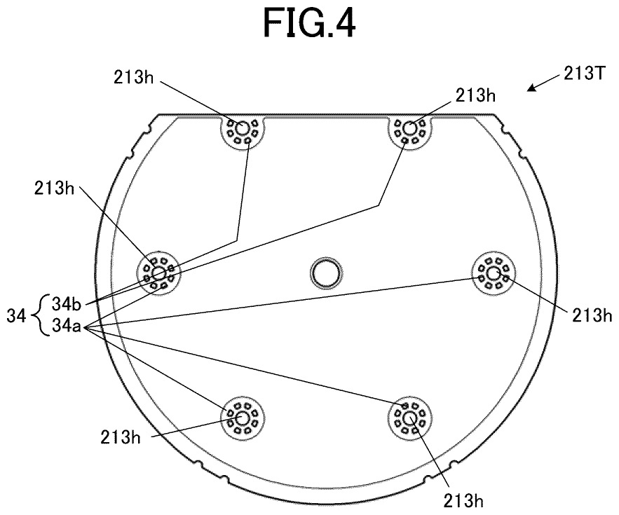

FIG. 4 is a plan view showing a top surface 213T of a second circuit substrate 213.

The fourth connection pad 34 (fourth connector) is located on the top surface 213T (third surface) of the second circuit substrate 213. The fourth connection pad 34 includes a fourth connection pad group 34a that overlaps the location of the second connection pad group 32a on the bottom surface 211B of the first circuit substrate 211 in plan view and a fourth connection pad group 34b that overlaps the second connection pad group 32b. Therefore, when the first circuit substrate 211 and the second circuit substrate 213 are aligned and screw-tightened and fixed, each of the fourth connection pads 34 is electrically connected to the corresponding second connection pad 32. In other words, when the first circuit substrate 211 and the second circuit substrate 213 are tightened by the screw S, it is easy to obtain reliable continuity between the second connection pad 32 and the fourth connection pad 34.

Furthermore, the location of these second connection pad 32 and fourth connection pad 34 overlap at least a portion of each with the extent of the projecting portion 221 of the analog block 22 in planar perspective. In other words, during screw tightening, the first circuit substrate 211 and the second circuit substrate 213 are supported from below in the direction of insertion of the screw S, that is, in the vertical direction by the projecting portions 221 with locally high rigidity and intensity. This ensures that the fourth connection pad 34 and the second connection pad 32 are pressed together.

The plan view shape of the first circuit substrate 211 and the second circuit substrate 213 do not necessarily have to be the same. If necessary, either plan view shape may partially protrude or depress with respect to the other plan view shape.

FIG. 5 shows a partial cross-sectional view of an electronic module 20 including one projecting portion 221. In this diagram, the screw S is omitted.

As described above, in the electronic module 20, the analog block 22 and the circuit 21 are located on top of each other. The projecting portion 221 protruding toward the side of the first circuit substrate 211 relative in the supporter 220 of the analog block 22 is facing and in contact with the first circuit substrate 211 at the opposing surface 221f. The projecting portion 221 is provided with the hole 221h. The post 222 is located inside the hole 221h. The post 222 is provided with a screw hole 222h extending internally from its lower end along the direction of extension. An inner wall surface of the screw hole 222h includes a screw groove to engage the screw S.

The post 222 penetrates the first through hole 211h of the first circuit substrate 211. The post 222 is partially inserted into the second through hole 213h of the second circuit substrate 213. This facilitates alignment of the post 222 with the first circuit substrate 211 and the second circuit substrate 213. The portion of the head of the screw S that protrudes from the bottom of the second circuit substrate 213 is reduced by a space remaining at the bottom of the second through hole 213h in which the post 222 is not inserted.

As shown in FIG. 3A, FIG. 3B, and FIG. 4, the plurality of locations where the first circuit substrate 211, the second circuit substrate 213, and the analog block 22 are secured by the screw S may be distributed roughly evenly. Here, the six positions of the second through holes 213h are located in a regular polygonal or annular arrangement slightly closer to the edge than halfway between the center and the edge of the second circuit substrate 213 in plan view. The plan view position of the second through hole 213h also corresponds to the position of the first through hole 211h and the position of the projecting portion 221, as described above. Therefore, the pressure applied to the first circuit substrate 211 and the second circuit substrate 213 during screw tightening is distributed evenly, reducing distortion and damage to the first circuit substrate 211 and the second circuit substrate 213.

Thus, the first circuit substrate 211 is a relay substrate through which the signal is routed when the signal is exchanged between the second circuit substrate 213 and the analog block 22. Here, the first connector on the top surface 211T of the first circuit substrate 211 corresponds to the position of the third connector in the analog block 22. Along with this, the position of the second connection pad 32 on the bottom surface 211B of the first circuit substrate 211 corresponds to the position of the fourth connection pad 34 on the top surface 213T of the second circuit substrate 213. In other words, even if the position or number of parts in the analog block 22 changes, the second circuit substrate 213 can continue to be used as is if the position of the first connector and the signal wiring pattern on the top surface 211T of the first circuit substrate 211 is changed.

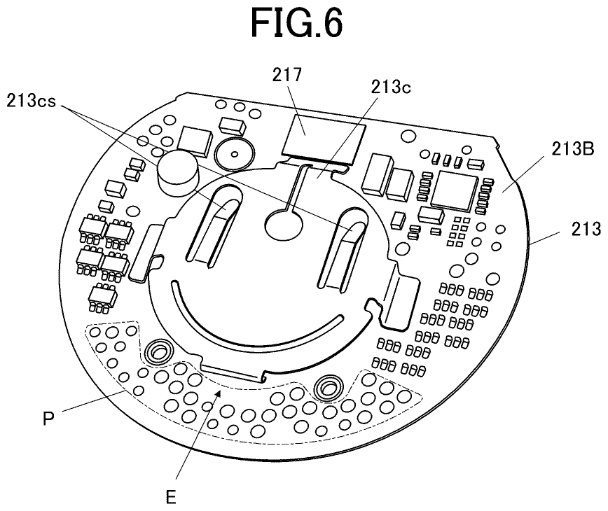

FIG. 6 is an oblique view showing the bottom surface 213B of the second circuit substrate 213.

This oblique view is from the opposite side of the second circuit substrate 213 shown in FIG. 2, that is, from the side of the insertion port E. In the battery compartment 213c, the battery is inserted and removed in a direction along the second circuit substrate 213 via the insertion port E. In other words, the direction in which the battery is attached and removed is indicated by the bold arrow. The battery inserted in the battery compartment 213c is secured by leaf springs 213cs. The battery, for example, includes a button shape and may be a dry cell or a secondary cell. In the electronic module 20, no electronic components or other components protruding in the height direction from the bottom surface 213B are located in a range that prevents the insertion and removal of the battery through the insertion port E. For example, inspection pads P used for testing during manufacturing inspection may be aligned in this portion. By positioning the top surface (exposed surface) of the inspection pad P so that it is substantially flush with the bottom surface 213B of the second circuit substrate 213, it is possible to avoid the insertion and removal of the battery through the insertion port E being interfered.

### Second Embodiment

Next, the electronic module 20a according to the second embodiment is described.

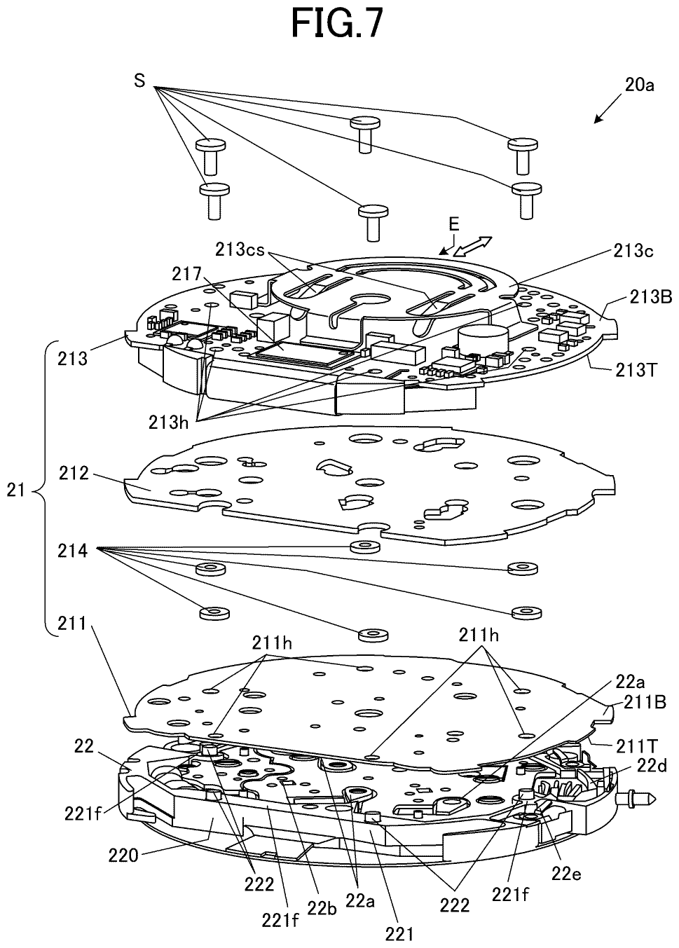

FIG. 7 is an exploded oblique view describing the structure of the electronic module 20a.

The electronic module 20a according to the second embodiment includes a spacer 212 and an inter-connector 214 between the first circuit substrate 211 and the second circuit substrate 213.

The spacer 212 is an insulating film that separates the first circuit substrate 211 from the second circuit substrate 213 to prevent short circuits. The spacer 212 also serves as a cushioning member for the projecting portion of the first circuit substrate 211 and second circuit substrate 213 on the surfaces facing each other. When the first circuit substrate 211 and the second circuit substrate 213 are screwed together, if there is unevenness between the opposing surfaces which are the bottom surface 211B and the top surface 213T, more local stress is applied to the projecting portion. Such stress makes the first circuit substrate 211 and the second circuit board 213 more susceptible to damage, etc. The spacer 212 relieves such stress and reduces the occurrence of breakage.

The spacer 212 is provided with a first through hole 211h, a second through hole 213h, and a through hole 212h including the post 222 in a plan view position. The through hole 212h is wider in plan view than the second through hole 213h in the second circuit substrate 213. The annular inter-connector 214 is located within this through hole 212h. In other words, the inter-connector 214 is located between the second connection pad 32 and the fourth connection pad 34. The inter-connector 214 does not allow continuity among the second connection pads 32 and among the fourth connection pads 34, which are annularly aligned around the post 222, as described above. On the other hand, the inter-connector 214 is anisotropically conductive so that it conducts between the opposing second connection pad 32 and the fourth connection pad 34. The thickness of the inter-connector 214 is about the same as the thickness of the spacer 212, which ensures contact between the second connection pad 32 and the fourth connection pad 34 and facilitates continuity.

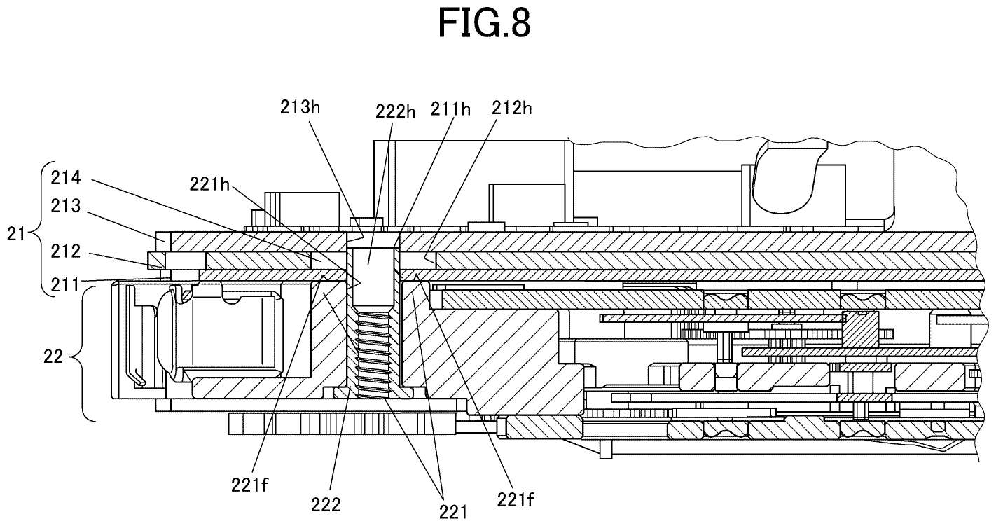

FIG. 8 shows a partial cross-sectional view of the electronic module 20a including one projecting portion 221 according to the second embodiment.

As described above, the thickness of the spacer 212 and the thickness of the inter-connector 214 are substantially identical, resulting in a layer of substantially uniform thickness between the first circuit substrate 211 and the second circuit substrate 213.

The post 222 penetrates through the first through hole 211h of the first circuit substrate 211 and the substantially center hole of the inter-connector 214 and extends into the second through hole 213h of the second circuit substrate 213. With this, the inter-connector 214 is properly aligned with the first circuit substrate 211 and the second circuit substrate 213. Alignment indexes (markings), and the like may be used when aligning the inter-connector 214 in the plane of the spacer 212 with respect to the direction of rotation. The alignment indexes may be located, for example, on each of the post 222, the first circuit substrate 211 or the spacer 212, and the inter-connector 214, respectively.

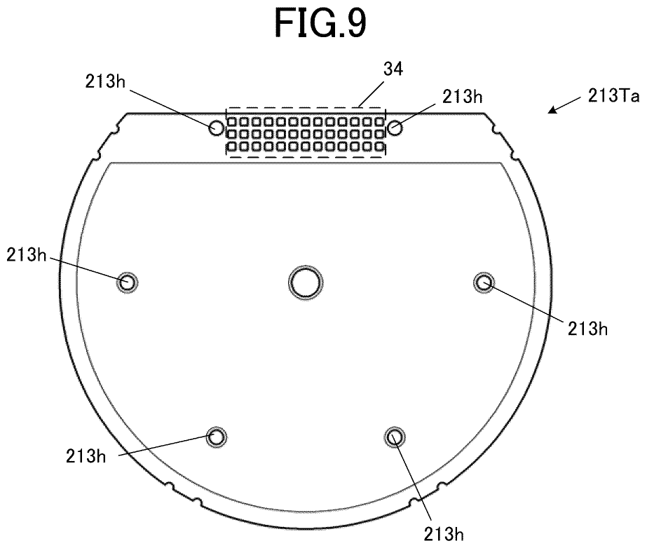

FIG. 9 is a plan view showing a top surface 213T of the second circuit substrate 213 according to a modified example.

The location of the fourth connection pads 34 may, for example, be located aligned between the two projecting portions 221. For example, the fourth connection pads 34 are arranged in a two-dimensional matrix in plan view, here in a belt shape. According to the sequence of the fourth connection pads 34, the location of the second connection pad on the bottom surface (fourth surface) of the second circuit substrate 213 is also in a two-dimensional matrix, or belt shape, in plan view.

As shown in FIG. 2, in the portion where the fourth connection pads 34 are lined up, the supporter 220 of the analog block 22 is thick in a belt shape so as to connect the posts 222 on both sides. Therefore, even with such a position of the fourth connection pad 34, distortion and damage of the first circuit substrate 211 and the second circuit substrate 213 can be reduced by screw tightening. The two ends of the array of the fourth connection pad 34 are screwed together to ensure continuity between the second connection pad 32 and the fourth connection pad 34.

As described above, the electronic modules 20 and 20a according to the present embodiment include the first circuit substrate 211, the analog block 22, and the second circuit substrate 213. The first circuit substrate 211 includes the first connector on the top surface 211T (first surface) and the second connection pad 32 on the bottom surface 211B opposite the top surface 211T, and the first connector and the second connection pad 32 are electrically connected. The analog block 22 includes the third connector, and the third connector is connected to the first connector of the first circuit substrate 211. The second circuit substrate 213 includes the fourth connection pad 34, and the fourth connection pad 34 is connected to the second connection pad 32 of the first circuit substrate 211. The position of the first connector and the position of the second connection pad 32 are different in planar perspective. The analog block 22 includes the projecting portion 221 that includes the opposing surface 221f, and such opposing surface 221f protrudes toward the first circuit substrate 211. The opposing surface 221f includes at least a partial range of the second connection pad 32 and the fourth connection pad 34 in planar perspective and faces the top surface 211T of the first circuit substrate 211.

According to the disclosure in JP 2018-9934, the substrate may need to be redesigned to accommodate changes in the analog block that is included in the electronic device. If all substrates are redesigned at this time, the time and cost per product model will increase.

The design of the first circuit substrate 211 of the electronic modules 20 and 20a can be modified according to the location and number of motors, light receiving elements, and other peripheral devices in the analog block 22. On the other hand, aligning the bottom surface 211B of the first circuit substrate 211 with the positioning of the second circuit substrate 213 eliminates the need to change the second circuit substrate 213 each time the design is changed. Thus, the labor and cost of dealing with changes in analog blocks for different models, such as design changes or model changes to the extent that they are controlled by the same microcomputer 217, is reduced. Thus, the electronic modules 20 and 20a can accommodate changes in analog blocks while limiting the increase in cost and labor.

The electronic module 20 includes the plurality of second connection pads 32. The second connection pads 32 may be divided into a plurality of groups, and a plurality of second connection pads 32 may be aligned in each group.

In other words, the plurality of second connection pads 32 may be arranged together on the surface that is stably supported by the projecting portion 221 when the circuit 21 and the analog block 22 are fixed. With this, in the electronic module 20, the second connection pad 32 and the fourth connection pad 34 are reliably in contact with each other, and continuity is easily obtained.

The first circuit substrate 211 may be provided with the first through hole 211h and the second circuit substrate 213 may be provided with the second through hole 213h. The analog block 22 includes the post 222 extending from the opposing surface 221f. The post 222 is inserted into the first through hole 211h and the second through hole 213h. This allows easy and accurate alignment of the analog block 22 including the post 222 with the first and second circuit substrates 211 and 213 each being provided with the first through hole 211h and second through hole 213h, respectively. Therefore, the labor involved in fixing these analog blocks 22, the first circuit substrate 211, and the second circuit substrate 213 is simplified and misalignment can be reduced.

The post 222 may also be provided with the screw hole 222h along the extending direction. The screw S screwed into the screw hole 222h can secure the first circuit substrate 211, the second circuit substrate 213, and the analog block 22 to each other. In this way, the analog block 22, the first circuit substrate 211, and the second circuit substrate 213 are secured by the screw S at the aligned positions, thus more securely fixing the electronic module 20 while reducing misalignment.

The first circuit substrate 211 includes the plurality of second connection pads 32. The plurality of second connection pads 32 may be arranged in an annular or circular arc around the first through hole 211h. The second connection pads 32 are evenly aligned in a radial position with respect to the central axis, and this facilitates equalization of the forces when the components are fixed. Therefore, the electronic modules 20 and 20a can reduce poor continuity between the second connection pad 32 and the fourth connection pad 34, or distortion and damage due to excessive force.

Alternatively, the projecting portion 221 may extend connecting the two posts 222 in planar perspective. The first circuit substrate 211 includes a plurality of second connection pads 32, and these may be arranged in a line or a belt shape along the projecting portion 221.

Even with this arrangement of the projecting portion 221 and the second connection pad 32, proper continuity between the second connection pad 32 and the fourth connection pad 34 can be ensured by screwing them together at the posts 222 at both ends.

The electronic module 20a may also include the inter-connector 214 between the second connection pad 32 of the first circuit substrate 211 and the fourth connection pad 34 of the second circuit substrate 213. In particular, if there are uneven parts between the first circuit substrate 211 and the second circuit substrate 213, such as the head of the screw, space will be provided around the above. Therefore, the increase in local stress on the first circuit substrate 211 and the second circuit substrate 213 is reduced. This allows the first circuit substrate 211 and the second circuit substrate 213 to be fixed more stably. In addition, more stable bonding and continuity is obtained between the second connection pad 32 and the fourth connection pad 34.

The analog block 22 includes the plurality of posts 222. The posts 222 may be located in a dispersed manner. The stress distribution between the first circuit substrate 211 and the second circuit substrate 213 is not unbalanced due to the distribution of locations that can support the connection between the second connection pad 32 and the fourth connection pad 34 in a stable manner. Therefore, distortion and damage are reduced during assembly of the electronic modules 20 and 20a to be fixed.

The plurality of posts 222 may be annularly positioned between the center and the edge of the second circuit substrate 213 in planar perspective. The fixing (screw tightening) between the first circuit substrate 211 and the second circuit substrate 213 is supported at a position not too close to the center or the edge. This prevents floating, etc. between the first circuit substrate 211 and the second circuit substrate 213, and also provides more reliable continuity between the second connection pad 32 and the fourth connection pad 34.

The electronic module 20 may also include the battery compartment 213c located on the bottom surface 213B opposite the top surface 213T where the third connection pad 33 of the second circuit substrate 213 is located. By including a configuration that accommodates the battery on the bottom-most side of the electronic module 20, the battery can be easily mounted to the electronic timepiece 1.

The battery compartment 213c includes an insertion port E that allows insertion and removal of the battery in a certain direction along the bottom surface 213B. The electronic components protruding from the bottom surface 213B are not located to the extent that they interfere with the insertion and removal of the battery through the insertion port E. With this, the battery can be easily removed and attached. The electronic timepiece 1 can also reduce the possibility of damaging components on the second circuit substrate 213 when the battery is removed or inserted.

Alternatively, the electronic module 20 according to the present embodiment includes the first circuit substrate 211, the analog block 22, and the second circuit substrate 213. The first circuit substrate 211 includes the first connector on the top surface 211T (first surface) and the second connection pad 32 on the bottom surface 211B opposite the top surface 211T, and the first connector and the second connection pad 32 are electrically connected. The analog block 22 includes the third connector, and the third connector is connected to the first connector of the first circuit substrate 211. The second circuit substrate 213 includes the fourth connection pad 34, and the fourth connection pad 34 is connected to the second connection pad 32 of the first circuit substrate 211. The position of the first connector and the position of the second connection pad 32 are different in planar perspective. The first circuit substrate 211 may include the phototransistor 216 that detects light entering from the side of the analog block 22. Here, the second circuit substrate 213 includes the microcomputer 217 that executes processing based on detected results by the phototransistor 216.

In other words, the phototransistor 216 which is the electronic component, is directly mounted to the circuit substrate. The fact that the circuit substrate to which the component is directly mounted is the first circuit substrate 211 eliminates the need to adjust the number and position of the components in the second circuit substrate 213, which is the common substrate. In other words, the phototransistor 216 being positioned on the individually designed first circuit substrate 211 increases the degree of freedom regarding the placement of the phototransistor 216. The phototransistor 216 will be located on the first circuit substrate 211, which is closer to the analog block 22 and thus the display surface than the second circuit substrate 213. This allows the electronic timepiece 1 to reduce the loss of incident light and improve detection sensitivity. Furthermore, there is no need to prepare further substrates for directly mounting the phototransistor 216 in addition to the first and second circuit substrates 211 and 213. Therefore, the electronic module 20 can accommodate changes in the analog block while reducing the increase in labor and cost per product model.

The electronic timepiece 1 according to the present embodiment includes the electronic module 20 described above. Such electronic timepiece 1 reduces the labor and cost involved in developing models that do not vary greatly in performance but differ slightly in function and design. Therefore, it is possible to develop multiple models of products more quickly and at a lower cost than with conventional techniques.

The present invention is not limited to the above embodiments, and various modifications are possible.

For example, the second connection pad 32 and the fourth connection pad 34 may not be located around the projecting portion 221, of which there are multiple pairs. One combination of second and fourth connection pads 32 and 34 may be located for each of the multiple projecting portions 221.

On the other hand, the plurality of combinations of second and fourth connection pads 32 and 34 corresponding to a certain projecting portion 221 may be grouped together as combinations that lead to the same type of configuration in the analog block 22. Alternatively, the combination of the second and fourth connection pads 32 and 34 may be randomly located.

The shape of the second through hole 213h may include a structure appropriate for screw tightening, such as a stepped structure.

In the above, the post 222 is long enough to be inserted into the first through hole 211h and the second through hole 213h, but it is not limited to this. If alignment is easily possible with other methods, the post 222 may be shorter than the length of the first through hole 211h, i.e., the thickness of the first circuit substrate 211. The height of only some of the plurality of posts 222 may be longer than the thickness of the first circuit substrate 211.

In addition, the above description assumes that all of the projecting portions 221 at locations corresponding to the second connection pad 32 includes the post 222 extending from them, but it is not limited to this. There may be a mixture of the projecting portion 221 that includes the post 222 that is screwed, and the projecting portion 221 that does not include the post 222 and that is not screwed. Even in this case, the position of the screw S should be defined to the extent that there is no problem with continuity between the second connection pad 32 and the fourth connection pad 34.

In the first embodiment above, the second connection pads 32 were arranged in an annular or arc shape in planar perspective, but it is not limited to this. The second connection pads 32 may be lined up in a frame-like pattern or at skipping angular intervals depending on the number of second connection pads 32. The projecting portion 221 may also be rectangular or other shapes instead of circular in plan view according to such an alignment. On the other hand, in the modification example, the fourth connection pad 34, that is, the second connection pad 32, is lined up in a band shape, but it is not limited to this. The fourth connection pad 34 may be arranged in a straight line. Alternatively, the fourth connection pad 34 may be located in a toothless alignment from the two-dimensional matrix. If the fourth connection pad 34 and the second connection pad 32 are arranged completely two-dimensionally, it may be difficult to set up a proper signal wiring pattern. Therefore, the fourth connection pad 34 and the second connection pad 32 may be lined up without the fourth connection pad 34 and the second connection pad 32 at the points necessary to obtain the proper pattern of signal wiring.

The post 222 does not have to extend further downward to penetrate through the projecting portion 221. The structure may include the post 222 overlapping on the projecting portion 221. In this case, the screw hole 222h may extend across the projecting portion 221 and the post 222.

In the above, the post 222 is arranged in an annular (hexagonal) shape in plan view, but it is not limited to this. For example, if the planar shape of the circuit 21 is not isotropic, the post 222 may be dispersed and located according to the unevenness of the circuit 21.

In the above, it is assumed that the phototransistor 216 is used for position detection of the hand 51 and for determining the transition to sleep mode, but either of these may be used. Alternatively, the phototransistor 216 may be used for further other applications.

Other than the electronic timepiece 1, the above disclosure may also be useful in cases where multiple designs are developed for small portable electronic devices.

Other specific components, configurations, connection relation of the signal lines, functions, operation contents, and the like as described in the above embodiments may be suitably changed without leaving the scope of the invention. The scope of the invention includes the scope of the claims and their equivalents.

What is claimed is:

1. An electronic module comprising:
a first circuit substrate that includes, a first connector on a first surface, and a second connector on a second surface on an opposite side of the first surface, wherein the first connector and the second connector are electrically connected;
an analog block that includes a third connector, wherein the third connector is connected to the first connector of the first circuit substrate; and
a second circuit substrate that includes a fourth connector, wherein the fourth connector is connected to the second connector of the first circuit substrate,
wherein,
a position of the first connector is different from a position of the second connector in planar perspective, and
the analog block includes a projecting portion that includes an opposing surface opposing to the first surface of the first circuit substrate and including at least a partial range of the second connector and the fourth connector, wherein the opposing surface is projected toward the first circuit substrate.

2. The electronic module according to claim 1, wherein,
a plurality of the second connectors are provided, and
the second connectors are divided into a plurality of groups, and the plurality of second connectors are aligned in each group.

3. The electronic module according to claim 2, further comprising an inter-connector between the second connector of the first circuit substrate and the fourth connector of the second circuit substrate.

4. The electronic module according to claim 1, wherein,
the first circuit substrate is provided with a first through hole,
the second circuit substrate is provided with a second through hole,
the analog block includes a post that extends from the opposing surface, and
the post is inserted in the first through hole and the second through hole.

5. The electronic module according to claim 4, wherein,
the post is provided with a screw hole along an extending direction, and
the first circuit substrate, the second circuit substrate, and the analog block are fixed to each other by a screw screwed in the screw hole.

6. The electronic module according to claim 4, wherein,
the first circuit substrate includes a plurality of second connectors, and
the plurality of second connectors are arranged in an annular or circular arc shape around the first through hole.

7. The electronic module according to claim 4, wherein,
the projecting portion extends to connect two of the posts in planar perspective,
the first circuit substrate includes a plurality of second connectors, and
the plurality of second connectors are aligned in a line shape or a belt shape along the projecting portion.

8. The electronic module according to claim 4, wherein,
the analog block includes a plurality of the posts, and
the plurality of the posts are annularly dispersed between a center and an edge of the second circuit substrate in planar perspective.

9. The electronic module according to claim 1, further comprising a battery compartment positioned on a fourth surface opposite a third surface in which the third connector of the second circuit substrate is positioned,
wherein,
the compartment includes an insertion port that is configured to allow the battery to be inserted and removed in a direction along the fourth surface, and
the electronic component protruding from the fourth surface is not positioned in a range that interferes with inserting and removing the battery through the insertion port.

10. The electronic module according to claim 1, wherein,
a position of the first connector is different from a position of the second connector in planar perspective,
the first circuit substrate includes a light receiving element that detects light incident from a side of the analog block, and
the second circuit substrate includes a controller that performs processing based on a detected result by the light receiving element.

11. An electronic module comprising:
a first circuit substrate that includes, a first connector on a first surface, and a second connector on a second surface on an opposite side of the first surface, wherein the first connector and the second connector are electrically connected;
an analog block that includes a third connector, wherein the third connector is connected to the first connector of the first circuit substrate; and
a second circuit substrate that includes a fourth connector, wherein the fourth connector is connected to the second connector of the first circuit substrate,
wherein,
a position of the first connector is different from a position of the second connector in planar perspective,
the first circuit substrate includes a light receiving element that detects light incident from a side of the analog block, and
the second circuit substrate includes a controller that performs processing based on a detected result by the light receiving element.

12. The electronic module according to claim 11, wherein,
a plurality of the second connectors are provided, and
the second connectors are divided into a plurality of groups, and the plurality of second connectors are aligned in each group.

13. The electronic module according to claim 1, further comprising a battery compartment positioned on a fourth surface opposite a third surface in which the third connector of the second circuit substrate is positioned,
wherein,
the compartment includes an insertion port that is configured to allow the battery to be inserted and removed in a direction along the fourth surface, and
the electronic component protruding from the fourth surface is not positioned in a range that interferes with inserting and removing the battery through the insertion port.

14. An electronic timepiece comprising:
the electronic module according to claim 1,
wherein the first circuit substrate of the electronic module includes at least a computer that controls a timekeeping operation.

15. An electronic timepiece comprising:
the electronic module according to claim 2,
wherein the first circuit substrate of the electronic module includes at least a computer that controls a timekeeping operation.

16. An electronic timepiece comprising:
the electronic module according to claim 4,
wherein the first circuit substrate of the electronic module includes at least a computer that controls a timekeeping operation.

17. An electronic timepiece comprising:
the electronic module according to claim 11,
wherein the first circuit substrate of the electronic module includes at least a computer that controls a timekeeping operation.

18. An electronic timepiece comprising:
the electronic module according to claim 12,
wherein the first circuit substrate of the electronic module includes at least a computer that controls a timekeeping operation.
